(19) United States
(12) Patent Application Publication
(10) Pub. No.: US 2009/0314343 A1
(43) Pub. Date: Dec. 24, 2009

(54) PV MODULE AND METHOD FOR MANUFACTURING PV MODULE

(75) Inventors: Kaoru Okaniwa, Ibaraki (JP); Takehiro Shimizu, Hsinchu City (TW); Hiroaki Morikawa, Hyogo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: HITACHI CHEMICAL CO., LTD., Tokyo (JP); MITSUBISHI ELECTRIC CORPORATION, Tokyo (JP)

(21) Appl. No.: 12/524,082

(22) PCT Filed: Feb. 26, 2008
(86) PCT No.: PCT/JP2008/053309

§ 371 Date: Jul. 22, 2009

(30) Foreign Application Priority Data
Feb. 28, 2007 (JP) 2007-050351

(51) Int. Cl. H01L 31/0216; H01L 31/18

(52) U.S. Cl. 136/256; 438/72; 257/E21.158; 257/E31.119

(57) ABSTRACT

Provided is a photovoltaic (PV) module by which electric power generation efficiency can be improved by improving light use rate. An encapsulant (202) is permitted to be a first layer (A cover glass (201) and the encapsulant (202) are considered optically equivalent, since their refractive indexes are substantially the same), a light trapping film (300) to be a second layer, an anti-reflective layer (104) to be a third layer, and an n-type layer (103) to be a fourth layer. When the reflective indexes of the layers are expressed as first reflective index (n₁), second reflective index (n₂), third reflective index (n₃) and fourth reflective index (n₄), relationship n₁≦n₂≦n₃≦n₄ is satisfied. The light trapping film (300) of the second layer, i.e., one layer among the light transmitting layers, has a structured shape on an incident side (300a) where incident light (205) enters.

### TECHNICAL FIELD

The present invention relates to a photovoltaic (PV) module and a method for manufacturing the PV module, and more specifically, a PV module in which incident light is more efficiently guided into the PV module improving the efficiency of power generation and a method for manufacturing this PV module.

### BACKGROUND ART

A conventional silicon crystal type PV module is described in cited non-patent document 1 below. A conventional PV module will now be described with reference to the schematic illustration (cross-sectional drawing) of FIG. 1. This conventional PV module comprises a solar cell 100, a cover glass 201, an encapsulant 202, a tab 203 and a back film 204.

Incident light 205 meets the cover glass 201 provided at the incident side. Reinforced Glass, applied with impact resistance can be used for this cover glass 201. In order to facilitate strong adhesion contact with the layered encapsulant 202, a side 201b of the cover glass 201 is embossed to create an uneven shape thereon. This uneven shape is formed on the inner surface, that is to say, on the lower surface of the cover glass 201 in FIG. 1, while the surface 201a of the PV module is smooth.

The encapsulant 202 is generally a resin comprised chiefly of ethylene-vinyl acetate copolymer. The encapsulant 202 seals the solar cell 100. The solar cell 100 converts incident light 205 introduced therein via the cover glass 201 and the encapsulant 202, into electric power. A multicrystal silicon substrate or a single crystal silicon substrate for example, can be used for the solar cell 100. Further, a back film 204 is formed on the side opposite to the aforementioned incident side of the encapsulant 202.

Moreover, in the cited patent document 1 below, a PV module is disclosed that employs a moth-eye configuration, thereby enabling external light from various angles including diagonal angles to be efficiently used without reflection loss, as it is taken in to the PV module. Another configuration in which external light is efficiently taken in without reflection loss is disclosed in cited nonpatent document 2 below, in which a transparent part is formed of a conical shape, a triangular pyramid shape or a quadrangular pyramid.
Nonpatent document 1: Yoshihiro Hamakawa “Solar Generation” Latest Technology and Systems, CMC Co. Ltd. 2000.
Nonpatent document 2: Hiroshi Toyota, Antireflection Structured Surface, Optics Volume 32 No. 8, page 489,2003.
Patent document 1: Japanese Patent Application Laid-Open No. 2005-101513

### DISCLOSURE OF THE INVENTION

### Problems to be Solved by the Invention

In the case of the above described conventional PV modules the problem is that significant difference in the respective refractive indexes of the solar cell 100 and the encapsulant 202 means that light reflection (of the incident light 205) arises at the boundary face, meaning that the light is inefficiently utilized.

Further, normally the configuration of the solar cell 100 involves forming a textured structure on the silicon substrate by applying an etching process in order to achieve a light trapping effect. However open circuit voltage V_{oc} is greater when the textured structure is not formed than when it is. This is because open circuit voltage V_{oc} is greater where there is less dependence on the pn contact area formed on the solar cell 100. That is to say in the case of conventional, high efficiency PV modules, due to the forming of a textured structure the increase in electric current compensates for and exceeds the deterioration in open circuit voltage V_{oc}.

With the foregoing in view the object of the present invention is to provide a PV module having improved power efficiency through more efficient light usage and a method for manufacturing this PV module.

It is a further object of the present invention to provide a PV module that avoids the problem of deterioration in open circuit voltage V_{oc} and a method for manufacturing this PV module.

### Means of Solving the Problems

In order to solve the above described problems, the PV module related to the present invention provides a PV module that generates electric power in response to incident light having layered members including a plurality of layers with light transmitting properties (light transmitting layers in which, starting from the side from which incident light enters, this plurality of light transmitting layers comprise a first layer, a second layer, . . . m-th layer, and the respective refractive indexes of this plurality of light transmitting layers are first refractive index n₁, second refractive index n₂, . . . m-th refractive index nₘ, where n₁≦n₂≦ . . . nₘ, moreover, at least one layer from among the light transmitting layers is a light trapping film having an uneven shape on the incident side where the incident light enters, the refractive index of which is 1.6-2.4.

In this PV module the value of normalized light absorption ‘a’ of the light trapping film, as shown in the following mathematical expression (1), should preferably be 0.1 or less when the wavelength of the incident light is 400-1200 nm.

$$\begin{matrix}[ Mathematical Expression 1 ] & \\ a [ - / µm ] = \frac{- {log}_{10} ( T )}{L} & ( 1 )\end{matrix}$$

Here, T is the transmittance, L is the average thickness (μm) of the film.

Again, it is preferable that between the light trapping film that is over solar cell that converts incident light into electric power and the solar cell, an anti-reflective layer equivalent to one of the layers from among the light transmitting layers is formed, and that the refractive index of this light trapping film is lower than the refractive index of the anti-reflective layer on the solar cell.

Moreover, it is preferable that by adjusting the refractive index of the light trapping film and that of the anti-reflective layer the efficiency of light guidance to the solar cell by the light trapping film is improved.

Further, it is preferable that a mold film, the incident side of which where the incident light enters having an uneven shape, is placed over the light trapping film, and that the refractive index of that mold film is less than the refractive index of the light trapping film.

It is preferable that the light trapping film is an organic-inorganic hybrid composition including titanium tetra alkoxide.

Further, it is preferable that the solar cell that converts incident light into electric power uses a solar cell formed by having a silicon substrate providing a rough surface formed by slicing in a mechanical process, which substrate is then subjected to etching to remove damage sustained on the surface mainly when the slicing was performed, and is not actively subjected to processes to form an uneven shape thereon.

Again, it is preferable that the solar cell that converts incident light into electric power uses a solar cell formed by having a silicon substrate providing a rough surface formed by slicing in a mechanical process, which substrate is then subjected to etching using an aqueous solution including 0.25 mol/l alkali hydroxide to remove damage sustained on the surface mainly when the slicing was performed, and is not actively subjected to processes to form an uneven shape thereon.

Moreover, it is preferable that a nitrous silicon film comprised of Si, N and H the refractive index of which is within the range from 1.8-2.7 is used for the anti-reflective layer of the solar cell.

Further, it is preferable that the silicon nitrate film used for the anti-reflective layer be formed by the plasma CVD method using as the raw material, a compound gas of SiH₄ and NH₃, under conditions in which the flow ratio of the SiH₄ and NH₃ compound gas is 0.05-1.0, pressure in the reaction chamber is 0.1-2 Torr, the temperature when forming the film is 300-550° C. and the frequency for plasma discharge is not less than 100 KHz.

In order to solve the above described problems, the method for manufacturing the PV module according to the present invention is a method of manufacturing a PV module that generates electric power in response to incident light, by having layered members including a plurality of layers with light transmitting properties (light transmitting layers) comprising the steps of forming a solar cell by forming on a silicon substrate at least an anti-reflective layer for preventing the reflection of incident light and electrodes on the front and back surfaces, forming a module by forming on the anti-reflective layer of the solar cell formed by the cell formation process, a light trapping film that traps incident light, then encapsulating the solar cell with an encapsulant, while in the module formation step the refractive index of the light trapping film is made less than the refractive index of the anti-reflective layer and moreover, greater than the refractive index of the encapsulant.

An important point about the present invention is the relationship of the refractive indexes of each respective layer. By controlling the refractive indexes of the inorganic film over the cell such as a silicon nitride layer or titanium oxide layer, greater effects are achieved in the current invention than the invention disclosed in patent document 1 above in which the object is achieved by controlling the refractive index of the light trapping film alone.

Because in the present invention the light trapping film has an optical confirming effect, it is not necessary for the cell to have a textured structure thereby avoiding the problem of open circuit voltage V_{oc} deterioration.

### Effects of the Invention

The present invention realizes improved light use rate (power generation efficiency) in a PV module and avoids the problem of deterioration in open circuit voltage V_{oc}.

### BRIEF DESCRIPTION OF THE DRAWINGS

FIG. 1 is a cross-sectional drawing of a conventional PV module;

FIG. 2 is a cross-sectional drawing of the best mode for carrying out the PV module according to the present invention;

FIG. 3 is a cross-sectional drawing of the PV module;

FIG. 4 is a cross-sectional drawing showing the condition in which a mold film is applied over a light trapping film;

FIG. 5 is a cross-sectional drawing showing a configuration in which a PV module has a light trapping film with adhered mold film applied, disposed over the solar cell;

FIG. 6 shows the processing sequence for applying the light trapping film to the solar cell;

FIG. 7 shows the steps in the manufacturing process for the first embodiment of a silicon solar cell;

FIG. 8 shows the characteristics when assessing reflection rate wavelength dependency both before and after a light trapping film is applied to the multicrystal silicon solar cell;

FIG. 9 shows the steps in the manufacturing process where a textured structure is not formed on a p-type silicon substrate in the case of the second embodiment; and

FIG. 10 is a flowchart showing the method of formation of the trapping film required in the fourth embodiment.

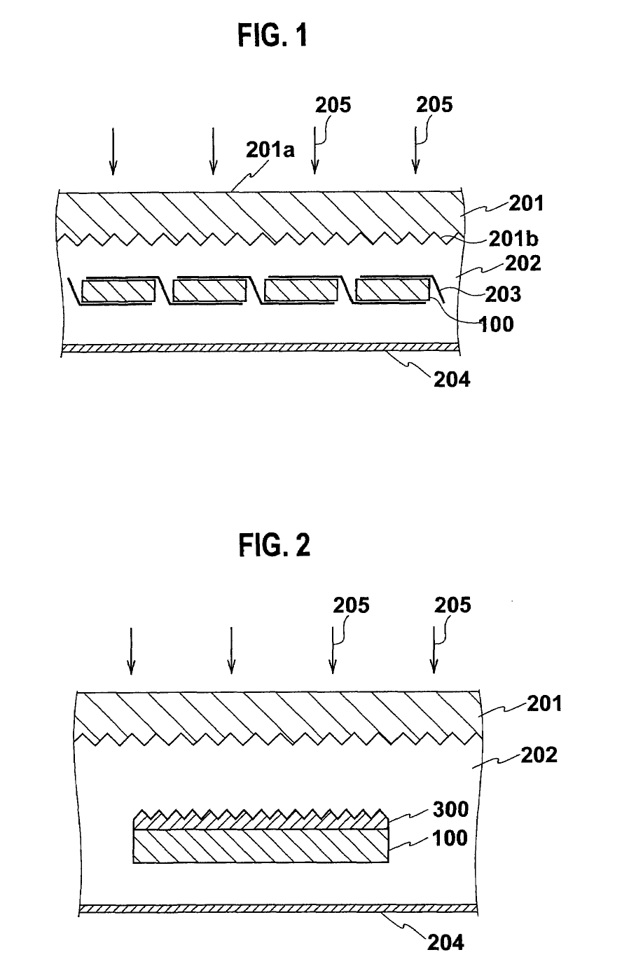

### BRIEF DESCRIPTION OF THE REFERENCE SYMBOLS

100 Solar cell
101 p-type silicon substrate
102 Textured structure
103 n-type layer
104 Anti-reflective layer
201 Cover glass
202 Encapsulant
300 Light trapping film
301 Mold film
302 Light trapping film seating part
303 Light trapping film structured shape part
304 PET film
305 High refractive index resin composition layer in semi-hardened state
306 PP film

### BEST MODE FOR CARRYING OUT THE INVENTION

The best mode for carrying out the invention will now be described with reference to the drawings. FIG. 2 is a cross-sectional drawing of a PV module employing a silicon substrate as the material for a solar cell.

This PV module is a module that generates electric power when incident light 205, entering from the incident side by passing a plurality of light transmitting layers including a cover glass 201, encapsulant 202 and light trapping film 300, is guided into the solar cell 100. The light transmitting layers in this case indicate the configuration, providing a concrete example of the structure. Another configuration could include for example providing an anti-reflective layer over glass in front of the cover glass 201 at the incident light side. In the case of conventional PV modules however, an anti-reflective layer over glass is not usual, neither is it essential for the present invention.

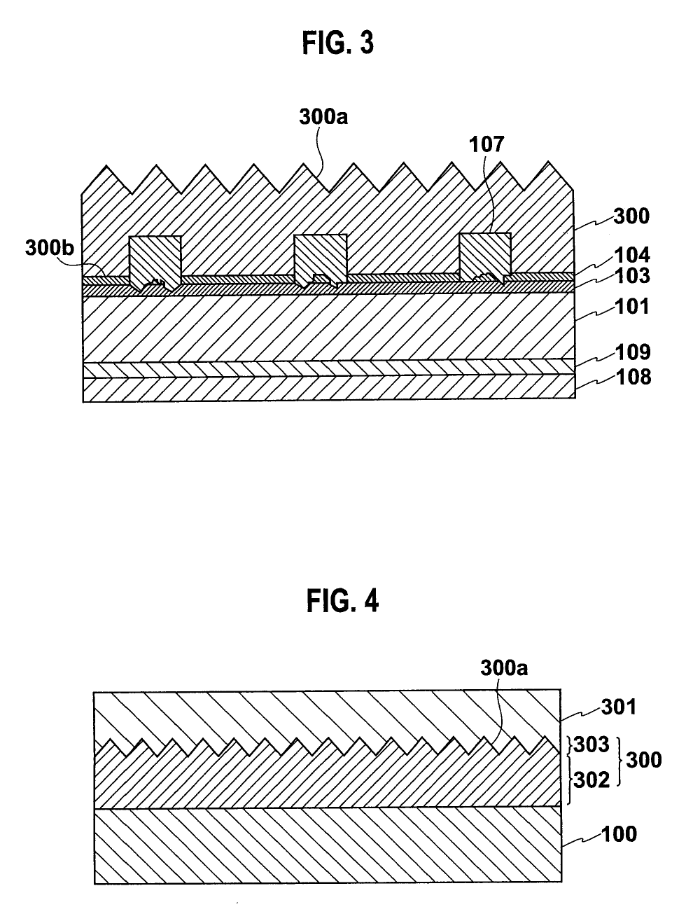

FIG. 3 is a cross-sectional drawing of the PV module 100 in detail. As shown in FIG. 3 the light trapping film 300 is applied at the incident side of the solar cell 100. The solar cell 100 comprises a p-type silicon substrate 101, an n-type layer 103, an anti-reflective layer 104, a front surface electrode 107, a back surface electrode 108, a p+layer 109 and the light trapping film 300. The light trapping film 300 is in contact with the anti-reflective layer 104.

The solar cell 100 is a silicon crystal arrangement solar cell that employs a multicrystal silicon substrate or single crystal silicon substrate, using for example the p-type silicon substrate 101 of a thickness of a few hundred μm. The n-type layer 103 is formed uniformly on the surface of the p-type silicon substrate 101.

The anti-reflective layer 104 is formed at an uniform thickness over the surface of the n-type layer 103. The anti-reflective layer 104 prevents unnecessary reflection of incident light efficiently trapped by the light trapping film 300, and employs for this a silicon nitride film having a refractive index in the range of 1.8-2.7, structured of silicon Si, nitrogen N or hydrogen H. This layer should be of a thickness in the range of 70-90 nm. Titanium oxide can be used for the anti-reflective layer 104.

A paste for a surface electrode is formed over the anti-reflective layer 104, moreover the surface electrode 107 is formed on this surface electrode paste.

The light trapping film 300 is adhered over the anti-reflective layer 104. As described above, on one side 300a of the light trapping film 300 a multiplicity of conical shapes or multi-angle pyramids of micro protrusions or micro recessions are formed spreading so as to cover the side 300a uniformly. These multi-angle pyramids are each of substantially the same form. The conical shapes also are of substantially the same form. The side 300a is formed on the incident side (where the incident light 205 enters), while the opposite side 300b of the incident side is in contact with the anti-reflective layer 104 of the solar cell 100. It is also suitable to have uneven shapes formed without interlude therebetween on the surface of the solar cell 100.

The light trapping film 300 has a refractive index of 1.6-2.4. In order that light from external sources (incident light 205) can be taken in from a variety of different angles while minimizing reflection loss, efficiently guiding light into the solar cell 100, the refractive index for the light trapping film 300 should be higher than that of the encapsulant 202, moreover it should be lower than that of the anti-reflective layer 104 over the solar cell 100; thus the refractive index for the light trapping film 300 should be in the range of 1.6-2.4 and more preferably 1.8-2.2.

Using an organic-inorganic hybrid compound including titanium tetra alkoxide provides a material for the light trapping film 300 having a high refractive index. The light trapping film 300 is also optically hardened, and can be made into a film shaped film by subjecting a base film such as PET or the like to a casting process for example. It is then covered using a separator film such as PP or the like. When the solar cell 100 is laminated, the light trapping film 300 is layered on the solar cell 100 after the separator film of PP or the like is peeled off, before lamination using a vacuum lamination process.

The multiplicity conical shapes or multi-angle pyramids of micro protrusions or micro recessions of the light trapping film 300 as described above, are formed using a mold film as described subsequently. Briefly, a mold film formed spread with multiple micro protrusions or recessions uniformly and without intervals therebetween is laid over the light trapping film 300, before a vacuum lamination process is once again employed in a structure replication process. Thereafter the mold film is peeled off and the light trapping film 300 is hardened through UV irradiation. It is also suitable to layer the mold film on the light trapping film 300 without removing it.

Aluminum paste for the back surface side is formed on the side opposite the above described incident side (front side) of the p-type silicon substrate 101, and the back surface side electrode 108 is formed thereon. Further, a BSF (Back Surface Field) layer 109 providing improved electric power generating capacity is formed by the reaction of the aluminum in the aluminum paste on the back surface side with the silicon on the back surface side to form a p+layer.

The PV module shown in FIG. 2 employing the solar cell 100 shown in FIG. 3 has for example the encapsulant 202 as a first layer (the refractive indexes of the cover glass 201 and the encapsulant 202 are considered optically equivalent), the light trapping film 300 as a second layer, the anti-reflective layer 104 as a third layer and the n-type layer 103 as a fourth layer; and when the refractive indexes of the layers are expressed as first refractive index n₁, second refractive index n₂, third refractive index n₃ and a fourth refractive index n₄, the relationship n₁≦n₂≦n₃≦n₄ is satisfied. The light trapping film 300 comprising the second layer, that is one layer among the light transmitting layers, has an uneven shape thereon as described above, on the incident side 300a where the incident light 205 enters. Specifically, the light trapping film 300 is formed having a multiplicity conical shapes or multi-angle pyramids of micro protrusions or micro recessions spreading so as to cover it uniformly.

Moreover, in the light trapping film 300, as shown in mathematical expression (2), the value of normalized light absorption a is not greater than 0.1 where the wavelength of the incident light is 400-1200 nm.

$$\begin{matrix}[ Mathematical Expression 2 ] & \\ a [ - / µm ] = \frac{- {log}_{10} ( T )}{L} & ( 2 )\end{matrix}$$

Here, T is the light transmittance and L the average thickness of the film (μm).

Consider now production of the PV module shown in FIGS. 2 and 3. Ideally, the distribution of the refractive indexes of the respective layers should be such that the refractive index becomes continually higher moving from the shallower layers (“shallower” here meaning the smaller numbers among first, second . . . m numbers from the incident side). However, the anti-reflective layer 104 comprising the third layer and the n-type layer 103 comprising the fourth layer are formed at the cell formation process for forming the solar cell 100. The layers shallower than these, the cover glass 201, the encapsulant 202 and the light trapping film 300 (first and second layers) are formed at the module formation stage. For this reason, it has been difficult in the case of conventional technology to achieve a sequential refractive index distribution over each layer member.

In the present invention the refractive indexes of the anti-reflective layer 104 formed during the cell formation process and the light trapping film 300 formed during the module formation process are adjusted to obtain the optimum mutual balance. Basically, the refractive index n₂ of the light trapping film 300 is made less than the refractive index n₃ of the anti-reflective layer. While if in the module formation process the refractive index n₁ of the encapsulant 202 (first layer) is made less than the refractive index n₂ of the light trapping film 300 (second layer) the above expression n₁≦n₂≦n₃≦n₄ is realized.

In terms of physical configuration, the moth-eye structure is what realizes continually equivalent refractive indexes. However, as is evident by reference to non-patent document 2 the size of the fine pyramid form required there determines what order of light wavelength is guided into the module. In contrast to this, in the case of the present invention such a fine form is not required, while forms of not less than 10 μm that can be applied using ordinary metalworking for dies can be used. This is because rather than requiring a continuous equivalent refractive index distribution, the present invention uses optical paths and multiple reflection understood by reference to geometrical optics.

In this way, the present invention reduces reflection loss occurring at encapsulant/cell interface in conventional technology, optical interfaces resulting from module layer construction demanded by the production processes being employed, and enables a greater quantity of light to be introduced into the solar cell 100. Accordingly, the most important point about the present invention is that it provides a configuration that enables light to be more efficiently guided into the pn connecting part of the solar cell 100 as the light trapping film 300 has a higher refractive index than the encapsulant 202. Basically, the efficiency by which light is guided by the light trapping film 300 is maximized by adjusting the respective refractive indexes of the light trapping film 300 and the anti-reflective layer 104 over the solar cell 100.

Explained in other terms, a point about the present invention is that the structure optimizes refractive indexes by adjusting the refractive indexes of the light trapping film 300 and the anti-reflective layer 104 of the solar cell 100. For example it is not easy to change the refractive index of the cover glass 201 providing the outermost layer (incident side), of the encapsulant 202 comprising the next layer under, or of the n-type layer 103 inside the solar cell or of the p-type silicon layer 101 for example. The fact however that the refractive indexes of the light trapping film 300 and the anti-reflective layer 104 comprising the intermediate layers can be adjusted, means that the above described relationship n₁≦n₂≦n₃≦n₄ can be readily realized.

In more simple terms, because the refractive indexes of the cover glass 201 and the encapsulant 202 are substantially equivalent these can be considered as optically equivalent (refractive index n₁). Further, when there is refractive index n₂ of the light trapping film 300, refractive index n₃ of the anti-reflective layer 104 and the refractive index n₄ of the n-type layer 103, the following mathematical expression is desirable.

n₂=√(n₁ n₃)

n₃=√(n₂ n₄)

With concrete values inserted, we get n₁≈1.5, n₄≈3.4 calculated to give n₂≈1.97, n₃≈2.59.

The mold film used to form the arrangement of multiple micro protrusions and recessions spread over the light trapping film 300 without interludes therebetween will now be described. FIG. 4 shows the condition in which a mold film 301 is laid over the light trapping film 300. The mold film 301 is a film having formed thereon a multiplicity of micro protrusions or recessions with no interludes between them, that join so as to perfectly complement the protrusions or recessions formed on the side 300a of the light trapping film 300 by biting together perfectly with no gaps, thus providing a casting of the recessions or protrusions of the light trapping film 300.

The manufacturing procedures consist of laying the light trapping film 300 over the mold film 301 then using vacuum lamination to replicate the structure. Next, the mold film 301 is peeled off and the light trapping film 300 hardened by irradiation with UV light.

Referring to FIG. 2, the mold film 301 has been taken off, giving a structure of layered encapsulant 202. Here, the uneven shape of the light trapping film 300 is in a well filled condition without gaps so that gaps do not arise.

It is also possible however to dispense with the removal of the mold film 301 and to employ the light trapping film with mold film attached, in the condition layered on the light trapping film 300.

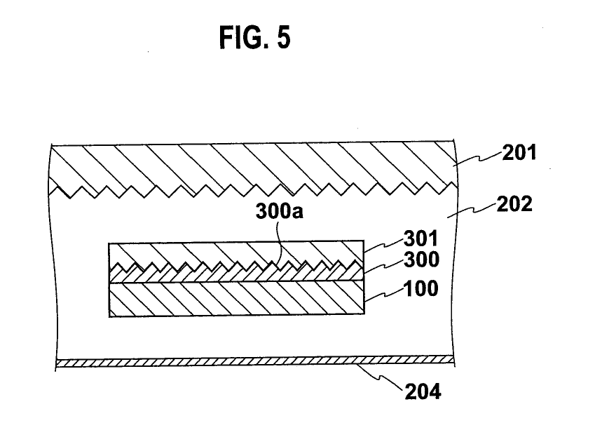

FIG. 5 is a structural drawing showing a configuration in which a PV module has a light trapping film 300 with adhered mold film 301 attached, disposed over the solar cell 100. The light trapping film 300 side is layered on the side of the solar cell 100. One surface of the light trapping film 300 traces, with no gap there between, the uneven shape on the front surface of the solar cell, and is adhered joining over the solar cell 100, layered as it is without removing the mold film 301 used for the protrusions or recessions, on the other surface 300a of the light trapping film 300. The external view provides a smooth appearance of light trapping film with mold film attached. The 301 used here has formed thereon without interludes therebetween, a multiplicity of micro protrusions and recessions that join (biting perfectly together with no gaps) complementing the micro protrusions and recessions on the side 300a with micro protrusions and recessions of the light trapping film 300, moreover, the refractive index of the mold film 301 is smaller than the refractive index n₂ of 300.

Each of the multiplicity of micro protrusions and recessions formed without interludes therebetween so as to spread over one side of the light trapping film 300 is of the form of a fine circular cone or a multiangular pyramid. In the non-reflective structure disclosed in cited nonpatent document 2 above, the finer the apex angle the more beneficial, but in the case of the present invention the light trapping film is sealed in a resin and as it is positioned abutting the solar cell that is distinguishable from the structure in nonpatent document 2.

In order to facilitate efficient direction of light incident from multiple angles into the solar cell, the finer the apex angle the more effective the structure, but where there is reflection loss at the boundary surface between the light trapping film 300 and the solar cell 100 then if that apex angle is too acute that reflected light may leak outside the structure. In order to enable the reflected light to be reflected again by the light trapping film 300 and smoothly returned into the solar cell 100, the apex angle should ideally be 90°. A 90° apex angle is most suitable in terms of performance and manufacturing precision.

According to cited nonpatent document 2 the size of the baseline is a value obtained by division of the shortest wavelength used by the refractive index of the material. Thus where the refractive index is 2.0, for the PV module it is approximately 175 nm. Obtaining the fine structure required however, is premised on the production method used.

The present invention however does not require this very fine structure. As shown in FIG. 4, the light trapping film 300 employed in the present invention can be considered as divided between the seating part 302 and the structured shaped part 303. The seating part 302 must be thicker enough, embedded following over the uneven form of the solar cell 100, so the thickness cannot exceed that of the uneven shape forms. Normally, a textured structure is applied to the front surface of the solar cell 100, the depths of which is 0-20 μm. On the other hand, the height of the multiplicity of micro protrusions and recessions, essentially a part of the light trapping film 300, formed so as to spread with regularity and without gaps on the light trapping film 300, should, due chiefly to the requirements of the mother mold production process, be 1-100 μm.

The light trapping film having a refractive index of 1.6-2.4, follows the uneven form of the cell as described above. Because the fine uneven form of the light trapping film original must be transferred, it is important to be of a resin compound material in a semi-hardened state. In the present invention an organic-inorganic hybrid composite material including titanium tetra alkoxide provides the light trapping film 300, realizing the high refractive index and enabling the form to be readily transferred.

That is to say, in a semi-hardened state, the light trapping film 300 is vacuum laminated onto the solar cell 100, and at this point is perfectly spread, embedded to cover the uneven form of the cell. Next, the separator film is peeled off and the mold film 301 with the fine uneven form of the light trapping film original is again vacuum laminated as the form is transferred. At this point it is suitable for the mold film 301 to be peeled off or to remain applied when the hardening process is performed. The method for hardening the resin composition may involve making the resin composition originally able to submit photo hardening processes or thermal hardening processes.

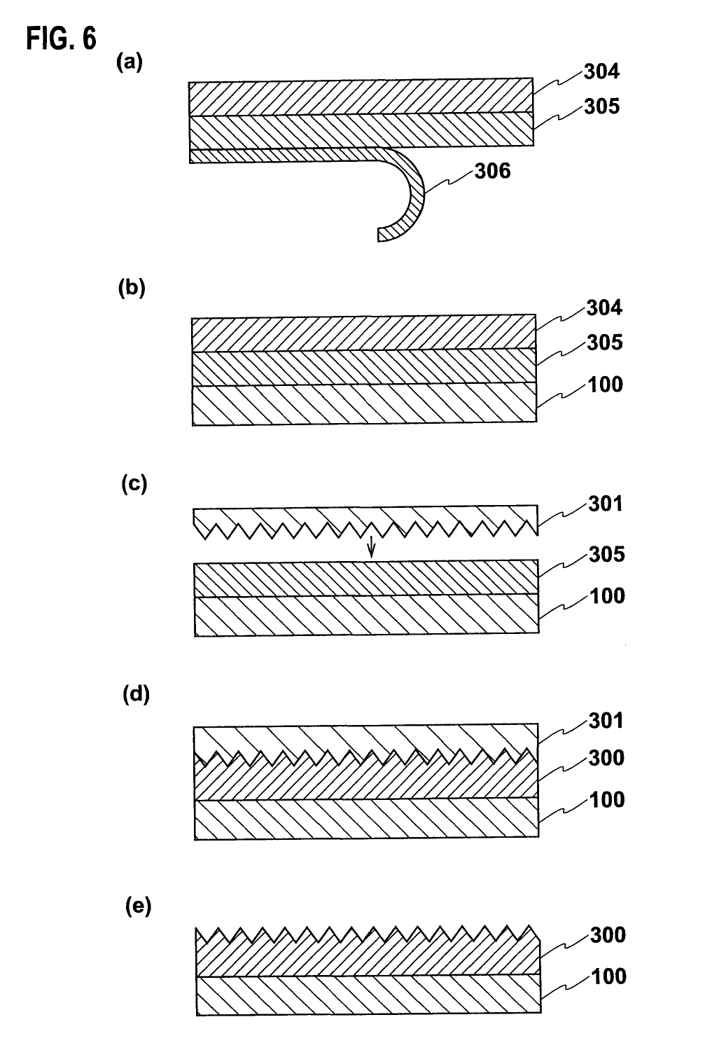

The procedures for applying the light trapping film 300 to the solar cell 100 will now be described in detail. FIG. 6 shows the processing sequence for applying the light trapping film 300 to the solar cell 100. A semi hardened state, high refractive index, resin compound 305 is used for the light traping film 300.

This semi-hardened state, high refractive index, resin compound 305 is of an organic-inorganic hybrid material including titanium tetra alkoxide, that can provide the high refractive index and be able to submit photo hardening. As shown in FIG. 6a the high refractive index, resin compound 305 is sandwiched between the PET film 304 and PP film (separator film) 306. Basically, the manufacturing process involves producing a film applied on a substrate PET film 304 of PET or like, which is then covered by a separator film 306 of PP or the like.

Then, as shown in FIG. 6b, at the lamination stage of the light trapping film onto the solar cell 100, after the separator film 306 of PP or the like is peeled off, the arrangement of the semi-hardened state, high refractive index, resin compound 305 and the PET film 304 is placed on the solar cell 100, before vacuum lamination is performed.

As shown in FIG. 6c and FIG. 6d, the mold film 301 formed having a multiplicity of micro protrusions and recessions so as to spread with regularity and without gaps arising, is then placed over the semi-hardened state, high refractive index, resin compound 305, before vacuum lamination is used once more to transfer the form.

The mold film 301 is then peeled off and the light trapping film 300 is hardened by irradiation with UV. In this way, when the form transference process is complete, the semi-hardened state, high refractive index, resin compound 305 can be hardened either by an photo or thermal hardening process. It is suitable for the mold film 301 to remain in this condition and be sandwiched between the cover glass 201, the encapsulant 202 and the back film 204 as the module is formed.

FIG. 6e shows the condition in which the mold film 301 has been peeled off, after the condition shown in FIG. 6d. After the mold film 301 is removed the module can be formed by sandwiching the arrangement between the cover glass 201, the encapsulant 202 and the back film 204.

At this time, where the cell textured structure is a depth of 10 μm and the depth of the uneven shape of the mold film is made 10 μm, the light trapping film (semi hardened state, high refractive index film) prior to lamination must be at least 20 μm thick. The seating part 302 of the light trapping film 300 should be 10 μm thick, and the structured part 303, 10 μm thick. For the present invention, there is no active formation of a textured structure, but as at the stage of slicing from a silicon ingot an uneven shape is left slightly on the surface, the dimensions of the seating part 302 must correspond to those of the uneven shape.

The organic-inorganic hybrid material for the semi-hardened state, high refractive index, resin compound 305 used as the light trapping film 300 will now be described.

In order to obtain the high refractive index in the present invention the sol-gel method is employed for the organic-inorganic hybrid material. The required composite for application of the sol-gel method here is a metal alkoxide expressed as

(R′)ₙM-(OR²)ₘ

In the present invention at least some of what is used is titanium tetra alkoxide expressed

Ti—(OR)₄.

A metal that complements this allows M to be selected from among Zn, Al, Si, Sb, Be, Cd, Cr, Sn, Cu, Ga, Mn, Fe, Mo, V, W, and Ce. For the R, the R¹ and R² of carbon numbers 1-10 have multiple bondings with M, but it is suitable for each to be the same or of different material. n is an integer not less than 0, and m an integer not less than 1 so n+m is equivalent to the valence of M. The metallic alkoxide used in order to obtain the organic-inorganic hybrid material by the sol-gel method may be just one type or a multiplicity.

In order to obtain the organic-inorganic hybrid material using the sol-gel method a metal alkoxide, water and an acid (or alkali) catalyst are added to a resin compound solution. This is then applied onto a substrate, a solvent is then evaporated by heating. Depending on the reactivity of the metal alkoxide selected however water and/or an acid (or alkali) catalyst may or may not be required. Further, the temperature of heating applied depends on the reactivity of the metal alkoxide. In the case of a highly reactive metal alkoxide like Ti or the like, water and catalyst are not required, and the heating temperature can be 100° C. For the present invention, a three dimensional structure (-M-O—) is not required for providing the high refractive index is sufficient. Especially in the case of titanium oxide, the three-dimensional structure produces a semiconductor as used for photo-catalyst. However, since the three dimensional structure occurs photo-degradation, the three-dimensional structure ought to be broken, thus it is effective to have another metallic alkoxide used in conjunction.

The mold film 301 (the mold film providing the uneven shape of the light trapping film) can be produced using the method disclosed in Japanese Patent Application Laid-Open No. 2002-225133. A concrete example of this method is described following.

Embodiment 1 will now be described.

### Embodiment 1

The solar cell used for the present invention can be effective when any generally produced solar cell is used but the structure of the solar cell 100 enabling it to realize greater efficiency as a PV module in the present invention, that operates with improved efficiency, and the method for producing this module will now be described.

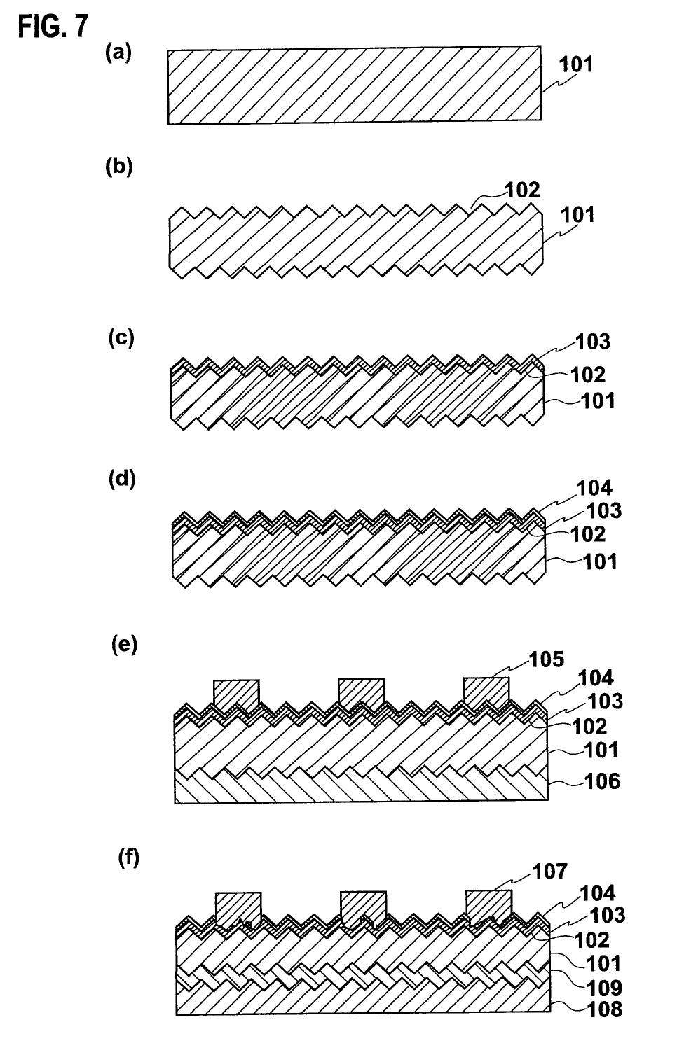

FIG. 7 shows the sequence of procedures a-f, which are the main steps in the production process, in a schematic illustration showing the cross-section of the silicon solar cell. FIG. 7f shows a complete the solar cell 100. In FIG. 7, 101 is the p-type silicon substrate, 102, the textured structure, 103 the n-type layer, 104, the anti-reflective layer 105, the front surface electrode silver paste, 106, the back surface electrode aluminum paste, 107, the front surface electrode, 108, the back surface electrode and 109 is the p+layer. This p+layer is a BSF (Back Surface Field) that improves the electric power generation capacity when the electrodes are sintered.

The manufacturing steps for the solar cell as illustrated in FIG. 7 will now be described. The kind of solar cells that are produced in the greatest number by mass production techniques presently are silicon crystal solar cells employing a multicrystal silicon substrate or single crystal silicon substrate, with the majority employing a p-type silicon substrate several hundred μm thick. The following explanation uses an example of a p-type silicon crystal substrate.

FIG. 7a shows the p-type silicon substrate 101. As shown in FIG. 7b, at the next step, after 10-20 μm thickness of the damaged layer of silicon surface arising when a slice is made from a ingot is removed using 3-20 wt % caustic soda or carbonic caustic soda, anisotropic etching is applied in a solution in which IPA (isopropyl alcohol) is added to the similar low alkali concentration solution, in order to expose the silicon face, thus forming the textured structure 102.

Generally, higher efficiency is achieved in a solar cell by forming the textured structure on the front surface side as disclosed in for example, Japanese Patent No. 3602323.

Then, at FIG. 7c the n-type layer 103 is formed uniformly on the front surface by a processing 20-30 minutes at 800-900° C. in a atmosphere consisting of a composite gas of phosphorus oxychloride (POC13), nitrogen and oxygen. Favorable electrical properties for the solar cell are obtained when the sheet resistance of the n-type layer 103 formed evenly on the silicon surface is within the range of 30-80 ω/mm². At this time the n-type layer 103 is formed over the entire surface of the substrate so it must be removed from the back surface side of the n-type layer 103. Thus in order to protect n layer at the light receiving surface side for example, after a high polymer resist paste is applied by screen printing method and dried, the n-type layer formed on silicon surfaces where it is not required, such as the silicon back surface for example, is removed by dipping for a few minutes in a solution of 20 wt % potassium hydroxide, removing the resist by an organic solution.

At FIG. 7d, the anti-reflective layer 104, a silicon nitride film, is formed at a uniform thickness over the surface of the n-type layer 103. For a silicon nitride film for example, the plasma CVD method is employed using as the raw material, a compound gas of SiH₄ and NH₃. Under conditions in which the flow ratio of the SiH₄ and NH₃ compound gas is 0.05-1.0, pressure in the reaction chamber is 0.1-2 Torr, the temperature when forming the layer is 300-550° C. and the frequency for plasma discharge is not less than 100 kHz, the optimum range for refractive index of the anti-reflective layer is 1.8-2.7, while the film thickness is 70-90 nm.

Next, at FIG. 7e, the front surface electrode paste 105 is applied using a screen printing method and dried. Here, the front surface electrode paste 105 is formed on the anti-reflective layer 104. Next, in the same way as for the front surface side, a back surface aluminum paste 106 is screenprinted and dried over the back surface also.

Then, at FIG. 7f, we have the solar cell in completed condition with electrodes sintered thereon. If sintered for several minutes at between 600-900° C., at the front surface side there is melting of the anti-reflective layer that is an insulating film, through the glass material included in the surface silver paste. Moreover, as part of the silicon surface melts, the silver material forms contacts to the silicon and is solidified, thereby enabling formation of electrical contacts. It is this phenomenon that maintains conductivity between the surface silver electrode and silicon. On the other hand, at the back surface side, the aluminum in the aluminum paste reacts with the back surface side silicon and the p+layer is formed, forming the BSF layer that improves electric power generating capacity.

The light trapping film is applied over the solar cell in this condition, by the method described above.

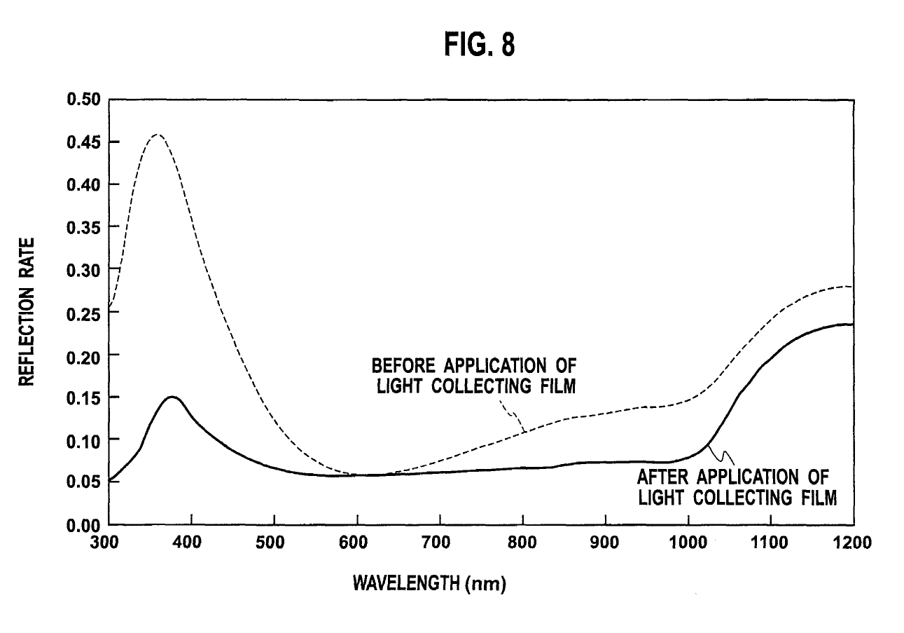

FIG. 8 shows the characteristics evident when evaluating reflectivity wavelength dependency both before and after a light trapping film is applied to the multicrystal silicon solar cell. Table 1 shows characteristics I-V of a multicrystal silicon solar cell both before and after application of a light trapping film, when a textured structure is formed and not formed. By applying the light trapping film short circuit current density (J_{sc}) increased from 32.22 mA/cm² to 32.78 mA/cm².

TABLE 1
Comparison of characteristics I-V of multicrystal silicon solar cell
both before and after application of a light trapping film, when a
textured structure is formed and not formed.

| Multicrystal | Light trapping | V_{oc} | J_{sc} | FF | E_{ff} |
|---|---|---|---|---|---|
| silicon cell | film | [V] | [mA/cm²] | [—] | [%] |
| Textured | Pre-application | 0.604 | 32.22 | 0.777 | 15.13 |
| structure | Post-application | 0.605 | 32.78 | 0.778 | 15.43 |
| formed | | | | | |
| Textured | Pre-application | 0.608 | 31.94 | 0.776 | 15.07 |
| structure and | Post-application | 0.610 | 32.76 | 0.778 | 15.55 |
| not formed | | | | | |

As shown in FIG. 8, when the light trapping film is applied the reflectivity substantially decreases, light absorbed inside the solar cell increases and there is an increase in electric current as expressed in characteristics I-V. Open circuit voltage (V_{oc}) also seems to increase roughly in coordination to the increase in current. Conversion efficiency (E_{ff}) improved 0.3%. Accordingly, it is confirmed that applying the light trapping film 300 to the solar cell 100 results in decreased reflectivity, and improved conversion efficiency in the PV module.

### Embodiment 2

The most efficient configuration among those structures in which a light trapping film is not applied to the solar cell are those in which reflection is reduced by forming a textured structure on the front surface side. The description of embodiment 1 shows the effects of applying the light trapping film on a solar cell structure which presently operates with high efficiency.

Now, in the description of embodiment 2, we assume that a light trapping film is applied, and describe how a still more highly efficient solar cell is obtained.

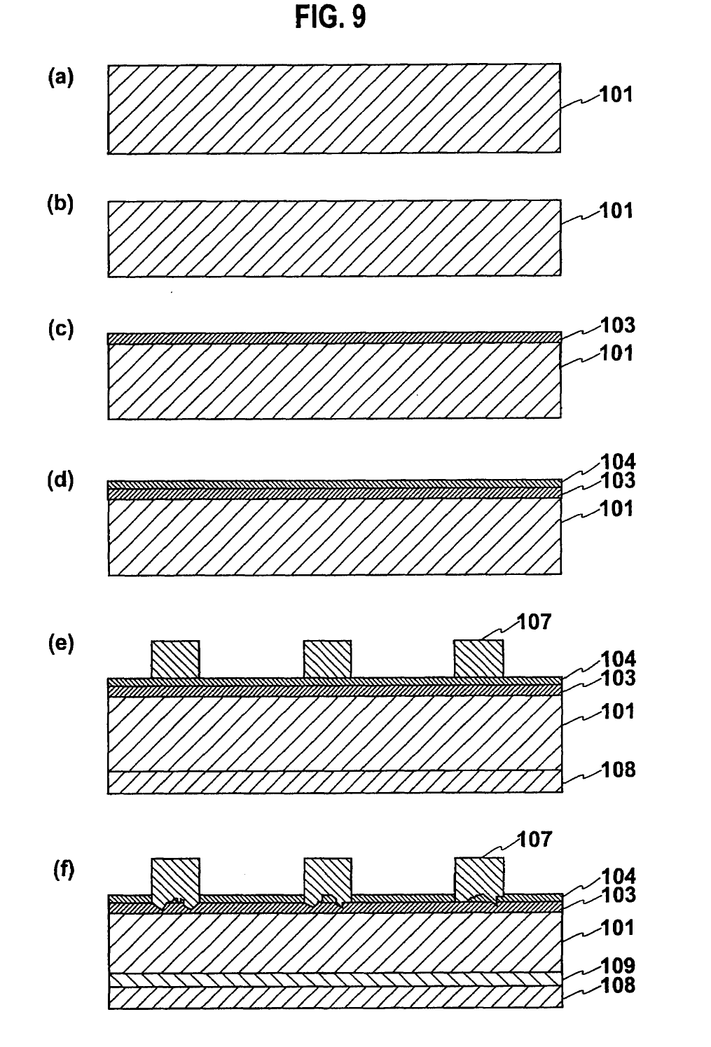

FIG. 9 shows the steps, a-f, in the manufacturing process where a textured structure is not formed on a p-type silicon substrate 101. FIG. 9f shows the completed condition of the solar cell 100.

FIG. 9a shows the p-type silicon substrate 101. At the next step, shown in FIG. 9b, 10-20 μm thickness of the damaged layer of silicon surface arising when a slice is made from a cast ingot is removed using 3-20 wt % caustic soda or carbonic caustic soda. A somewhat uneven shape is present on the surface however it is still smoother than if a textured structure were formed.

Then, at FIG. 9c, in the same manner as described with respect to FIG. 7c, the n-type layer 103 is formed at a uniform thickness on the front surface by a processing 20-30 minutes at 800-900° C. in a gaseous atmosphere consisting of a composite gas of phosphorus oxychloride (POC13), nitrogen and oxygen. At this time the n-type layer 103 is formed over the entire surface of the substrate so it must be removed from the back surface side of the n-type layer 103.

Then, at FIG. 9d, in the same manner as described with respect to FIG. 7d, the anti-reflective layer 104 of silicon nitride film is formed at a uniform thickness on the n-type layer 103. Next, at FIG. 9e, in the same manner as described with respect to FIG. 7e, the front surface electrode paste 105 is applied using a screen printing method and dried. Here, the front surface electrode paste 105 is formed on the anti-reflective layer 104. Next, in the same way as for the front surface side, a back surface aluminum paste 106 is screenprinted and dried over the back surface also.

Then, at FIG. 9f, in the same manner as applied with respect to the description of FIG. 7f, we have the solar cell in completed condition with electrodes sintered thereon. If sintered for several minutes at between 600-900° C., at the front surface side there is melting of the anti-reflective layer that is an insulator, through the glass material included in the surface silver paste. Moreover, as part of the silicon surface melts, the silver material forms conductive parts to the silicon fast, thereby enabling formation of electrical contacts. It is this phenomenon that maintains conductivity between the surface silver electrode and silicon. On the other hand, at the back surface side, the aluminum in the aluminum paste reacts with the back surface side silicon and the p+layer is formed, forming the BSF layer that improves electric power generating capacity. If a light trapping film is applied over the solar cell in this condition using the method described above, the solar cell is completed with a basically smooth form having no textured structure.

Table 2 shows a comparison of the results obtained for characteristics I-V where multicrystal silicon substrate is used, with no light trapping film, when a textured structure is formed and not formed.

TABLE 2
Comparison of characteristics I-V of multicrystal silicon solar cell,
when a textured structure is formed and not formed.

| Multicrystal | Cell | V_{oc} | J_{sc} | FF | E_{ff} |
|---|---|---|---|---|---|
| silicon cell | No. | [V] | [mA/cm²] | [—] | [%] |
| Textured | 1 | 0.605 | 32.16 | 0.778 | 15.13 |
| structure | 2 | 0.605 | 32.29 | 0.776 | 15.17 |
| formed | 3 | 0.603 | 32.16 | 0.779 | 15.11 |
| | 4 | 0.603 | 32.23 | 0.775 | 15.06 |
| | 5 | 0.604 | 32.22 | 0.777 | 15.13 |
| | Ave. Value | 0.604 | 32.21 | 0.777 | 15.12 |
| Textured | 1 | 0.608 | 31.70 | 0.779 | 15.01 |
| structure not | 2 | 0.609 | 31.67 | 0.775 | 14.95 |
| formed | 3 | 0.608 | 31.72 | 0.777 | 14.99 |
| | 4 | 0.608 | 31.77 | 0.776 | 14.99 |
| | 5 | 0.608 | 31.94 | 0.776 | 15.07 |
| | Ave. Value | 0.608 | 31.76 | 0.777 | 15.00 |

Table 2 shows the results measured for open circuit voltage V_{oc}, electric current density J_{sc}, FF and E_{ff} for five cells having a textured structure formed and five cells having no textured structure formed.

As shown in Table 2, when there is no light trapping film applied and the textured structure is formed, J_{sc} is greater while V_{oc} is small. J_{sc} is greater when there is a textured structure. As described above, this is because, in comparison to the case where the textured structure is not formed, the reflectivity is lower and more light is able to be absorbed. On the other hand, V_{oc} is greater when the textured structure is not formed than when it is. V_{oc} is dependent on pn contact area formed on the solar cell, and increases as this area decreases. When the textured structure is not formed this area is smaller and V_{oc} increases. That is to say as shown in Table 1, in the high-efficiency solar cells of the prior art, the increase in electric current resulting from formation of a textured structure compensates for and exceeds the decrease in V_{oc}.

Here, when the light trapping film is used, anti-reflection efficiency is improved by the film, thus, as a structure for a solar cell, this is the optimum configuration without employing a light trapping structure. That is to say, as shown in Table 1 not actively forming a textured structure results in greater V_{oc} than when a textured structure is formed. As described previously, the principle here is that the uneven shape is reduced, there is a reduction in pn contact area.

Table 1 shows characteristics l-V both before and after application of a light trapping film, when a textured structure is not formed. Short circuit current density J_{sc} increases, open circuit voltage V_{oc} exceeds the increase in short circuit current density J_{sc}. Due to the effects of the light trapping film however, short circuit current density J_{sc} is substantially equivalent as in the condition in which a textured structure is formed and light trapping film is applied. The result is that where the light trapping film is applied and the textured structure is not formed, conversion efficiency of increased V_{oc} is improved in comparison to the case in which the textured structure is formed.

### Embodiment 3

Embodiment 2 concerns the case in which a multicrystal silicon substrate is used, but the results obtained by employing a single crystal silicon substrate where a mirror surface is polished, when a textured structure is formed and not formed have also been confirmed. In the case of a multicrystal silicon substrate some of the uneven shape remains at the alkali etching when the damaged layer resulting from the slicing is removed, but if a single crystal silicon substrate with mirror surface specifications is used, it enables a mirror surface to be provided as the substrate surface. When mirror surface specifications are used it becomes possible to form what is basically the ideal uneven shaped structure when a textured form is created. Accordingly in comparison to the case in which a multicrystal silicon substrate is used, here, when employing a light trapping film the difference between having a textured structure formed or not formed can be more readily ascertained. The steps for manufacturing the solar cell according to this embodiment 3 are the same as those applied with respect to embodiment 1 and embodiment 2, the point of difference with this third embodiment being that a single crystal silicon substrate is employed for the substrate.

Table 3 shows a comparison of characteristics I-V for a single crystal silicon solar cell, when a textured structure is formed and not formed.

TABLE 3
Comparison of characteristics I-V of single crystal silicon solar cell,
when a textured structure is formed and not formed.

| Single crystal | Cell | V_{oc} | J_{sc} | FF | E_{ff} |
|---|---|---|---|---|---|
| silicon cell | No. | [V] | [mA/cm²] | [—] | [%] |
| Textured | 1 | 0.613 | 37.05 | 0.774 | 17.59 |
| structure | | | | | |
| formed | | | | | |
| Textured | 1 | 0.621 | 34.29 | 0.785 | 16.72 |
| structure not | | | | | |
| formed | | | | | |

In the same manner as was apparent for the configuration using a multicrystal silicon cell substrate, comparing the case in which a textured structure is formed against the case in which a textured structure is not formed we see that V_{oc} is lower, J_{sc} increases substantially, supplementing the deterioration in V_{oc} so that higher efficiency is realized.

Further, Table 4 describes the results when the light trapping film is formed.

TABLE 4
Comparison of characteristics I-V of single crystal silicon solar cell
both before and after application of a light trapping film, when a
textured structure is formed and not formed.

| Single crystal | Light trapping | V_{oc} | J_{sc} | FF | E_{ff} |
|---|---|---|---|---|---|
| silicon cell | film | [V] | [mA/cm²] | [—] | [%] |
| Textured | Pre-application | 0.613 | 37.05 | 0.774 | 17.59 |
| structure | Post-application | 0.615 | 37.23 | 0.775 | 17.74 |
| formed | | | | | |
| Textured | Pre-application | 0.621 | 34.29 | 0.785 | 16.72 |
| structure not | Post-application | 0.624 | 37.18 | 0.783 | 18.17 |
| formed | | | | | |

Here also, in the same manner as the case for the multicrystal silicon solar cell, regardless of whether the textured structure is formed or not formed, J_{sc} is basically the same, and it can be confirmed that when the textured structure is not formed V_{oc} is higher and to that extent, greater efficiency is realized.

### Embodiment 4

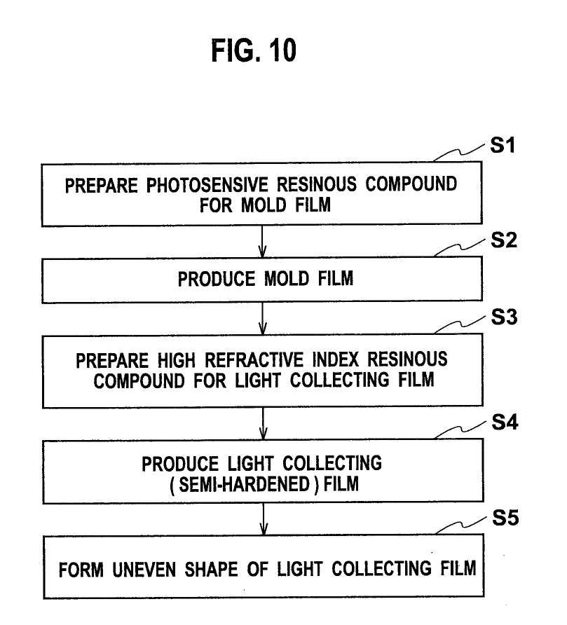

FIG. 10 is a flowchart showing the method of formation of the light trapping film. The method of forming the light trapping film comprises several steps. This method of applying the light trapping film will now be described with reference to FIG. 10.

Firstly, at step S1 a photosensitive resin compound is prepared for the mold film. Binder resin (component A) consisting of Hitaloid HA7885 (by Hitachi Chemical Co. Ltd.) 50 parts by weight; cross-linkable monomer (component B) Fancryl FA-321M (from Hitachi Chemical Co. Ltd.) 50 parts by weight; and a photoinitiator (component C) provided by IRGACURE184 (from Ciba Specialty Chemicals) 3.0 parts by weight. These are dissolved in an organic solvent, methyl ethyl ketone, to produce a varnish (a photosensitive resin composition). This varnish is used to form a film of approximately 5000 Å on a silicon wafer, the refractive index of which was 1.48 when measured using an ellipsometer.

Next, at step S2, the mold film is produced. 1-2 droplets of the photosensitive resin compound described above are dropped onto a die, having an effective area of 155 mm, a baseline of 20 μm and a height of 10 μm, in which a multiplicity of quadrangular pyramids are formed without intervals therebetween. Over this is placed 50 μm thick polyethylene terephthalate (PET) film (A-4300 by Toyobo Co. Ltd.,) that has been processed so as to enable adhesion on both surfaces. A roller is then used to remove any bubbles, preventing them from forming between the resin liquid and the PET, before UV light is used to irradiate the PET side. Peeling this PET film off the die produces a concave, quadrangular pyramid mold film.

Then, at step S3 the high refractive index resin compound for the light trapping film is prepared. After air gas is introduced into a reactor providing an agitator, a temperature gauge, cooling pipes and air inlet pipes: polycarbonate diol (product name PNOC-2000, number average molecular weight approximately 2000, by Kuraray Co. Ltd.) 4000 parts (hydroxyl group: 4.0 equivalent amount) comprising 1,9-nonanediol, 2-methyl-1,8-octanediol and diphenyl carbonate; 2-hydroxyethyl acrylate: 115 parts (hydroxyl group: 1.0 equivalent amount); hydroquinone monomethyl ether (by Wako Pure Chemical Industries Ltd.) 0.5 parts; dibutylin dilaurate (product name: L101, by Tokyo Fine Chemical Co. Ltd.) 5.0 parts; and toluene, 4000 parts are fed in. The temperature is raised to 70° C., and then maintained for 30 minutes at 70-75° C. A liquid mixture consisting of 4,4′-dicyclohexyl methylene diisocyanate (product name: Desmodur W, by Sumika Bayer Urethane Co. Ltd.) 650 parts (isocyanate group: 5.0 equivalent amount) and toluene, 300 parts, is uniformly dripped in over 3 hours at 70-75° C., and these are reacted until after it is confirmed, using IR measurement, that isocyanates are no longer present, at which point the reaction is stopped. To this is then added Igarcure-184 (by Ciba-Geigy) 30 parts, titanium tetra-i-propoxide 8000 parts, FA-712HM, by Hitachi Chemical Co. Ltd., 1600 parts, PET-3 by Dai-ichi Kogyo Seiyaku Co. Ltd., 3200 parts, and diethanolamine, 3000 parts. The whole is then agitated and dissolved together to obtain a urethane UV hardened resin composite.

At step S4 the light trapping film (semi-hardened) is produced. Using an applicator the high refractive index, urethane, UV hardening resin compound for the light trapping film is applied over PET film (the substrate). This is passed through a hot air convection dryer at 80-100° C. and dried for approximately 10 minutes to obtain a semi-hardened film. Over the applied film a separator film is placed, provided by PP film, to protect the semi-hardened film layer.

At step S5, the structured shape of the light trapping film is formed. After the separator film of the light trapping film is peeled off, the light trapping film is placed over the solar cell and laminated using a vacuum laminator. Then the PET providing the substrate of the film in a semi hardened state is peeled off and the structured shape surface of the above described mold film is pressed into the semi hardened state film, before the whole is passed again through the vacuum laminator thereby transferring the fine, structured shape onto the semi hardened film. The arrangement is then subject to optical irradiation using an exposure apparatus, hardening the film to become the light trapping film. The vacuum laminator used was by Meiki Co. Ltd., and the conditions for lamentation and the form transference require 75° C., with a pressure of 0.4 MPa, applied for 45 seconds. The exposure unit was a high-pressure mercury vapor lamp, the exposure conditions being 1000 mJ/cm².

1. A photovoltaic (PV) cell module that generates electric power in response to incident light, this module having layered members including a plurality of layers with light transmitting properties (light transmitting layers) wherein starting from the side from which incident light enters, this plurality of light transmitting layers comprise a first layer, a second layer, . . . m-th layer, and the respective refractive indexes of this plurality of light transmitting layers are first refractive index n₁, second refractive index n₂, . . . m-th refractive index nₘ, where n₁≦n₂≦ . . . ≦nₘ, and, at least one layer from among the light transmitting layers is a light trapping film having an structured shape on the incident side where the incident light enters, the refractive index of which film is 1.6-2.4.

2. The PV module according to claim 1 wherein the value of normalized absorbance a of the light trapping film, as shown in the following mathematical expression (3), should preferably be 0.1 or less when the wavelength of the incident light is 400-1200 nm,
$$\begin{matrix}[ Mathematical Expression 3 ] & \\ a [ - / µm ] = \frac{- {log}_{10} ( T )}{L} & ( 3 )\end{matrix}$$
wherein T is the transmittance, L is the average thickness (μm) of the film.

3. The PV module according to claim 1 wherein between the light trapping film that is over the solar cell that converts incident light into electric power and the solar cell, an anti-reflective layer equivalent to one of the layers from among the light transmitting layers is formed, and the refractive index of this light trapping film is less than the refractive index of the anti-reflective layer on the solar cell.

4. The PV module according to claim 1 wherein by adjusting the refractive index of the light trapping film and that of the anti-reflective layer the efficiency of light guidance to the solar cell by the light trapping film is improved.

5. The PV module according to claim 1 wherein a mold film, the incident side of which where the incident light enters having an structured shape, is placed over the light trapping film, and the refractive index of that mold film is less than the refractive index of the light trapping film.

6. The PV module according to claim 1 wherein the light trapping film is an organic-inorganic hybrid composition including titanium tetra alkoxide.

7. The PV module according to claim 1 wherein the solar cell that converts incident light into electric power uses a solar cell formed by having a silicon substrate providing a rough surface formed by slicing in a mechanical process, which substrate is then subjected to etching to remove damage sustained on the surface mainly when the slicing was performed, and is not actively subjected to processes to form an uneven shape thereon.

8. The PV module according to claim 1 wherein the solar cell that converts incident light into electric power uses a solar cell formed by having a silicon substrate providing a rough surface formed by slicing in a mechanical process, which substrate is then subjected to etching using an aqueous solution including 0.25 mol/l alkali hydroxide to remove damage sustained on the surface mainly when the slicing was performed, and is not actively subjected to processes to form an uneven shape thereon.

9. The PV module according to claim 3 wherein a silicon nitride layer comprised of Si, N and H the refractive index of which is within the range from 1.8-2.7 is used for the anti-reflective layer of the solar cell.

10. The PV module according to claim 9 wherein the silicon nitride layer used for the anti-reflective layer is formed by the plasma CVD method using as the raw material, a compound gas of SiH₄ and NH₃, under conditions in which the volume ratio of the NH₃/SiH₄ compound gas is 0.05-1.0, pressure in the reaction chamber is 0.1-2 Torr, the temperature when forming the film is 300-550° C. and the frequency for plasma discharge is not less than 100 kHz.

11. A method for manufacturing a photovoltaic (PV) module having layered members including a plurality of layers with light transmitting properties (light transmitting layers), that generates electric power in response to incident light, comprising the steps of:
forming a solar cell by forming on a silicon substrate at least an anti-reflective layer for preventing the reflection of incident light and electrodes on the front and back surfaces;
forming a module by forming on the anti-reflective layer of the solar cell formed by the cell formation process, a light trapping film that traps incident light, then encapsulating the solar cell with an encapsulant; wherein
at the module formation step the refractive index of the light trapping film is made less than the refractive index of the anti-reflective layer, and greater than the refractive index of the encapsulant.
